(19) United States
(12) Patent Application Publication
(10) Pub. No.: US 2007/0215451 A1
(43) Pub. Date: Sep. 20, 2007

(54) Mobile device arrangement including replaceable touch panel

(76) Inventors: Michael Sasloff, Hastings-on-Hudson, NY (US); Carl Thelemann, East Islip, NY (US)

Correspondence Address: FAY KAPLUN & MARCIN, LLP, 15O BROADWAY, SUITE 702, NEW YORK, NY, 10038, US

(21) Appl. No.: 11/377,526

(22) Filed: Mar. 16, 2006

(51) Int. Cl. H03K 17/975

(52) U.S. Cl. 200/600

(57) ABSTRACT

An electronic device, comprises a housing including circuitry mounted therein and a touch screen removably mounted on the housing so that a first surface of the touch screen faces out from the housing to display output and receive contact input from a user in combination with a plurality of first electrical contacts receiving from the touch screen electrical signals corresponding to the contact input, the first electrical contacts located on a second surface of the touch screen and a plurality of second electrical contacts coupled to the circuitry, the second electrical contacts being positioned so that, when the touch screen is mounted on the housing, each of the second electrical contacts electrically couples to a corresponding one of the first electrical contacts electrically coupling the touch screen to the circuitry.

### BACKGROUND

An inherent problem in many mobile devices relates to durability of a touch panel included therein. Due to continual intermittent pressure exerted upon the touch panel in everyday usage, the touch panels of mobile devices often become dislodged, worn, bent or cracked. Further, if the glass covering is cracked if the device is dropped or impacted may also damage an outer conductive layer of some types of touch panels.

The touch panels of conventional MD's are generally electrically coupled to internal circuitry by a flexible tail composed of one or more wires with one end of the tail coupled to the touch panel while the second end is coupled of the tail to a connector mated with a corresponding connector on a printed circuit board (“PCB”) internal to the device. Alternatively, the second end of the tail may be directly connected to the PCB. Thus replacement of these touch panels is difficult and often necessitates sending the device for service or replacing the device entirely.

### SUMMARY OF THE INVENTION

The present invention is directed to an electronic device comprising a housing including circuitry mounted therein and a touch screen removably mounted on the housing so that a first surface of the touch screen faces out from the housing to display output and receive contact input from a user in combination with a plurality of first electrical contacts receiving from the touch screen electrical signals corresponding to the contact input, the first electrical contacts located on a second surface of the touch screen and a plurality of second electrical contacts coupled to the circuitry, the second electrical contacts being positioned so that, when the touch screen is mounted on the housing, each of the second electrical contacts electrically couples to a corresponding one of the first electrical contacts electrically coupling the touch screen to the circuitry.

### BRIEF DESCRIPTION OF THE DRAWINGS

FIG. 1 shows an exemplary embodiment of a mobile device having a touch pad arrangement according to the present invention;

FIG. 2 shows an exemplary embodiment of an inner portion of a mobile device having a touch pad arrangement according to the present invention;

FIG. 3 shows an exemplary embodiment of an integration of the mobile device and the touch pad arrangement according to the present invention;

FIG. 4 shows another view of the exemplary embodiment of the integration of the mobile device and the touch pad arrangement shown in FIG. 3;

FIG. 5 shows another exemplary embodiment of an integration of the mobile device and the touch pad arrangement according to the present invention; and

FIG. 6 shows another view of the exemplary embodiment of the integration of the mobile device and the touch pad arrangement shown in FIG. 5.

### DETAILED DESCRIPTION

The present invention may be further understood with reference to the following description and the appended drawings, wherein like elements are referred to with the same reference numerals. The present invention will be described with reference to a touch panel utilized in a mobile device (e.g., a PDA, a palm sized personal computer, a cellular telephone, a global positioning system (GPS), a bar code scanner, a digital imager, a radio frequency identification (RFID) device, etc.). However, those skilled in the art will understand that the present invention is equally suited for any electronic device utilizing a touch panel, including stationary computing devices such as printers, copy machines, touch panel monitors, etc.

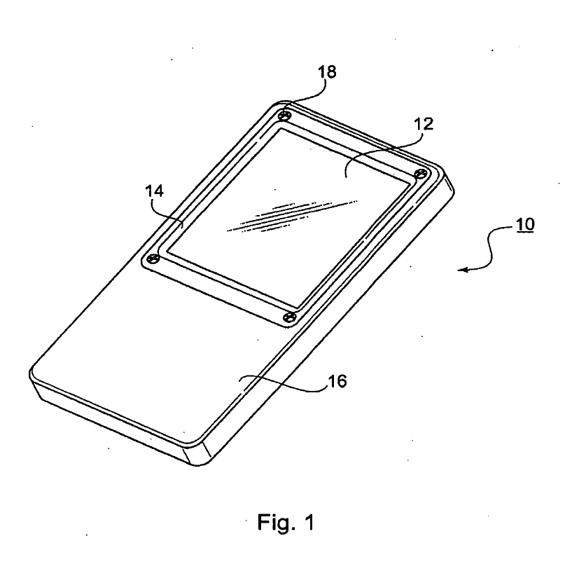

As shown in FIG. 1, a mobile device (“MD”) 10 includes a housing 16, a touch panel 12, and a frame 14 for the touch panel 12. The frame 14 is secured to the housing 16 by, for example, screws 18, or any other form of attachment (e.g., adhesive, integrally formed latches, mechanical fasteners, etc.). The housing 16 may be monocoque (i.e., substantially formed from one piece of material) or it may be formed from two or more pieces coupled to one another. For example, the housing 16 may be manufactured as two halves of material which are affixed together upon assembly. According to an embodiment of the present invention, the housing 16 may be manufactured utilizing a molding process, for example, injection molding, blow molding, compression molding, or extrusion molding. The material forming the housing 16 may be any substantially rigid material, such as a Polycarbonate, a Lucite, an Acrylic, a Perspex® or any combination thereof.

The housing 16 encases a number of internal components including, for example, the circuitry and battery of the MD 10. As would be understood by those skilled in the art, the circuitry may include, for example, an address/data bus for communicating information, a processor coupled with the bus for processing information and instructions, a volatile memory (e.g., random access memory) coupled to the bus for storing information and instructions for the processor and/or a non-volatile memory (e.g., read only memory) coupled to the bus for storing static information and instructions for the processor. The MD 10 may further include a data storage device (e.g., a memory stick) coupled to the bus to provide additional data and/or instruction storage.

The touch panel 12 of the MD 10 according to one embodiment of the present invention, is external to display information to a user and to receive input from the user in the form of contacts of areas of the screen corresponding to information currently displayed thereon. As would be understood by those skilled in the art, various possible arrangements of displays and different types of displays are suitable for use with the current invention. For example, the display may be an LCD, a cathode ray tube (CRT), a field emission device (FED, or flat panel CRT), or any other display suitable for generating images and/or alphanumeric characters recognizable to the user.

The touch panel 12 is electrically coupled to the circuitry of the MD 10 so that, as the touch panel 12 is actuated (e.g., touched by the user with a finger or stylus) the processor detects the actuation, determines a location of the actuation and a relationship between the location and an image portrayed on the display to determine an appropriate action (if any) to execute as a result of the actuation. For example, the display may output an image depicting a plurality of boxes, each representing a unique predetermined function. When a user selects one of these functions by touching the corresponding box (e.g., by hand or using a stylus), the processor determines the location of the actuation as within the selected box and executes the corresponding function.

Several different systems for detecting a point of contact exist including, but not limited to, a resistive system, a capacitive system, an inductive system, and a surface wave acoustic system. The resistive system includes a conductive metallic layer and a resistive metallic layer which are held apart by spacers. The two layers contact one another as they are pressed toward one another by the user contact with the transfer of electrical current allowing the exact location of the user contact to be identified. The capacitive system includes a capacitive layer which stores electrical charge transferred to item contacting the layer (e.g., a finger) causing a reduction in the charge on the capacitive layer which is detected to calculate the exact location of the touch. The inductive system determines the location of user actuation based on changes in the strength of a magnetic field deployed above the surface as a special stylus is moved over the surface. The surface wave acoustic system includes a pair of transducers, each working with a corresponding reflector which reflect an electrical signal sent by the transducer. Each transducer determines whether its signal has been disturbed by contact and the processor uses the data from the two transducers to locate the contact.

According to an embodiment of the present invention, circuitry for the touch panel 12 extends around the touch panel 12 to a surface of the touch panel 12 different from that on which the user touches the panel 12 (e.g., a surface facing an interior of the housing 16) to a plurality of touch panel contacts 30. In this embodiment, the touch panel contacts 30 are positioned so that, when the touch panel 12 is received within the housing 16 in a desired orientation, the touch panel contacts 30 are aligned with electrical contacts 20 coupled to main circuitry of the MD 10 to establish a connection between the touch panel 12 and the main circuitry of the MD 10 in response to user actuation.

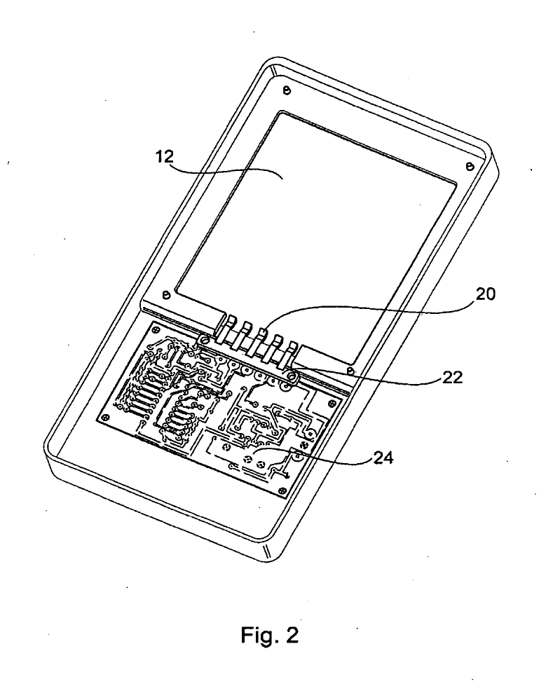

As shown in FIGS. 2-4, the electrical contacts 20 extend from an inner portion of the housing 16 toward an area at which an edge of the touch panel 12 including the touch panel contacts 30 is received when the touch panel 12 is mounted within the housing 16. The electrical contacts 20 may be any of a number of types, including but not limited to pogo pins and leaf springs to establish electrical contact with the touch panel contacts 30 as the touch panel 12 is slid into position within the housing 16. This type of connection then poses no bar to removing the touch panel 12 when service or replacement of this part is required. As would be understood by those skilled in the art, the touch panel contacts 30 and the electrical contacts 20 may be formed of any conductive material, such as silver, gold, copper, etc., and preferably rest flat against one another. Furthermore, the mechanical engagement of the electrical contacts 20 and the touch panel contacts 30 may be enhanced by any suitable means, including adhesive, solder, etc. so long as disassembly of the device by the user is not impeded. As would be understood by those skilled in the art, the electrical contacts 20 may be secured to the inner surface of the housing 16 by any suitable means including, for example, a plate 22.

Although the circuitry for the touch panel 12 is described as extending around the touch panel to the back surface (i.e., the surface opposite that on which user input is received), those skilled in the art will understand that the touch panel contacts 30 may be mounted on or extend from a side surface of the touch panel 12 with the electrical contacts 20 repositioned to engage the contacts 30. Furthermore, the circuitry of the touch panel 12 may extend through the touch panel 12 if desired.

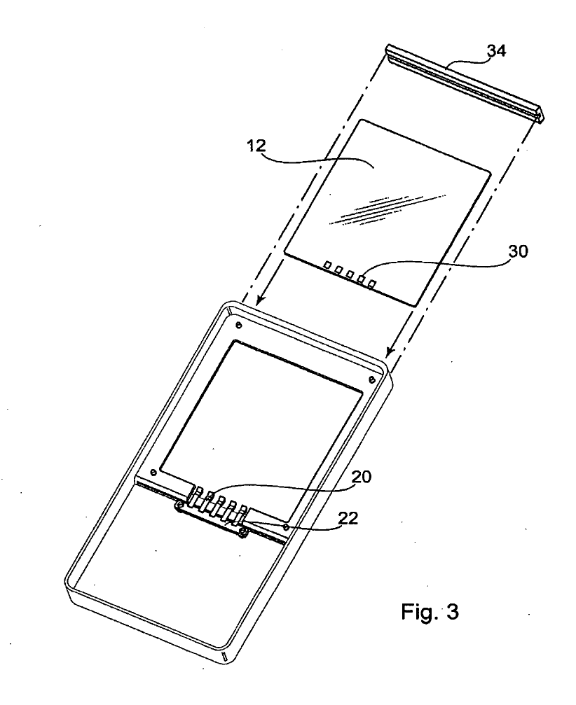

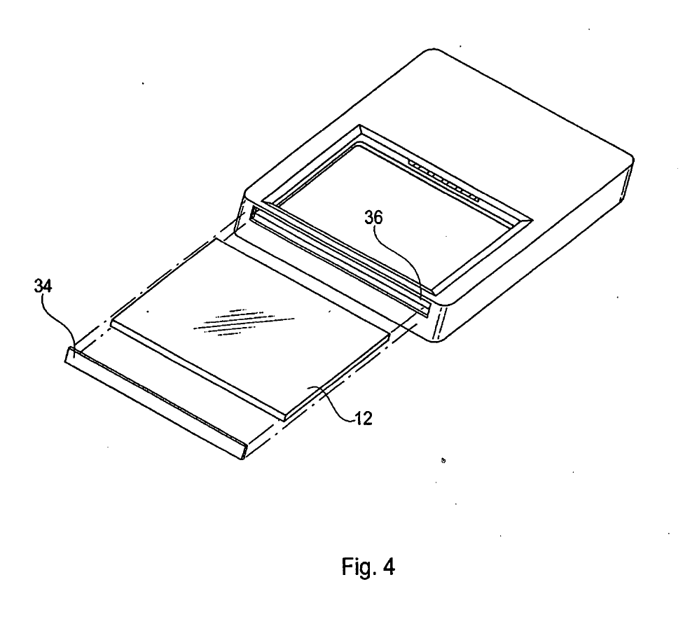

As shown in FIGS. 3 and 4 the touch panel 12 may be inserted into the housing 16 via an aperture 36 which may be located in any surface of the housing 16 and locked in place with a member 34 which removably seals the aperture 36. The member 34 is preferably coupled, for example, mechanically or adhesively, semi-permanently to the aperture 36 and/or the housing 16 so that a user may remove the member 34 without damaging the housing 16 or any other component of the MD 10. Thus, the touch panel 12 may be easily slid out of the MD 10 via the aperture 36 if, for example, it is damaged or destroyed.

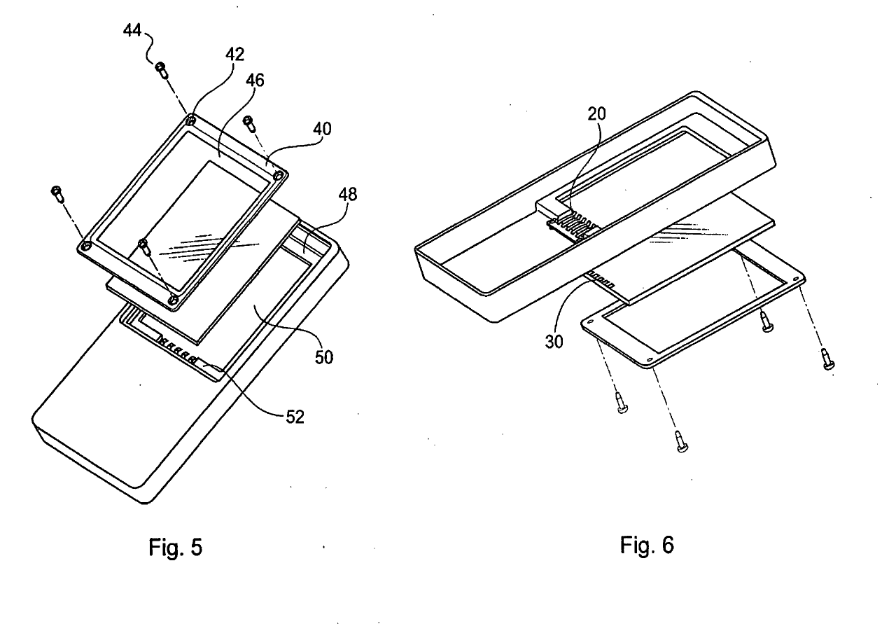

FIGS. 5 and 6 portray an exemplary embodiment of the present invention wherein the touch panel 12 is coupled to the housing 16 via a frame 40. As shown, an outer surface of the housing 16 includes a region 48 adapted to receive the touch panel 12. As would be understood by those skilled in the art, the size and shape of the region 48 is preferably selected to correspond to a size and shape of the touch panel 12 with, for example, a ledge 52 and a cutout 50 holding the touch panel in a desired location and orientation within the region 48 with the touch panel contacts 30 in alignment with the electrical contacts 20. Furthermore, those skilled in the art will understand that the touch panel 12 may be secured to the housing 16 by any known means including adhesive, mechanical fasteners, etc. so long as the touch panel 12 may be removed without damaging the housing and/or the touch panel 12.

As shown in FIGS. 5 and 6, the touch panel 12 according to a further embodiment of the invention is secured within the region 48 by a frame 40 including an opening 46 through which a user may access the touch panel 12. In the exemplary embodiment, the frame 40 contains holes 42, through which screws 44 may be inserted into corresponding holes in the housing 16 to tighten the frame 40 against the frame 16. Those skilled in the art will understand that the frame 40 may be tightened to compress the touch panel 12 against the housing 16 to enhance contact between the electrical contacts 20 and 30. Although a total of four screws is illustrated in this embodiment, it will be understood that any number of screws may be used to secure the assembled components of the mobile terminal.

According to this embodiment of the present invention, the touch panel 12 may also be easily removed from the housing 16 by removing the screws 44 and lifting the frame 40 from the touch panel 12. The user may then lift the touch panel 12 from the housing 16 for repair or replacement.

It will be apparent to those skilled in the art that various modifications and variations may be made in the structure and the methodology of the present invention without departing from the spirit or scope of the invention. Thus, it is intended that the present invention cover the modifications and variations of this invention provided they come within the scope of the appended claims and their equivalents.

1. An electronic device, comprising:
a housing including circuitry mounted therein;
a touch screen removably mounted on the housing so that a first surface of the touch screen faces out from the housing to display output and receive contact input from a user;
a plurality of first electrical contacts at least partially integrated with the touch screen and receiving from the touch screen electrical signals corresponding to the contact input, the first electrical contacts located on a surface opposite the first surface of the touch screen; and
a plurality of second electrical contacts coupled to the circuitry, the second electrical contacts being positioned so that, when the touch screen is mounted on the housing, each of the second electrical contacts electrically couples directly to a corresponding one of the first electrical contacts, thereby electrically coupling the touch screen to the circuitry.

2. The device of claim 1, wherein the device includes at least one of a bar code scanner, a digital imager, a GPS, a wireless transceiver, a PDA, a telephone and an RFID reader.

3. The device of claim 1, further comprising a bezel coupled to the housing and including a cutout aligned with the touch panel.

4. The device of claim 1, wherein the housing comprises a slot through which the touch screen may be inserted into the housing and a lid member removably coupled over the slot to lock the touch screen in a desired position within the housing.

5. The device of claim 4, wherein the lid member is semi-permanently coupled over the slot so that the lid member is removable from the housing without damaging the housing.

6. The device of claim 1, wherein the second electrical contacts include one of pogo pins and leaf springs.

7. The device of claim 1, wherein the first electrical contacts are bonded to the surface opposite the first surface of the touch screen.

8. The device of claim 1, wherein the first electrical contacts are releasably secured to the second electrical contacts by adhesive.

9. The device of claim 1, wherein the first electrical contacts are arrayed in a line along an edge of the surface opposite the first surface of the touch screen.

10. The device of claim 1, wherein the housing defines a touch screen receiving cavity sized and shaped to receive the touch screen and a bezel removably mounted over at least a portion of a periphery of the touch screen receiving cavity to retain the touch screen therein.

11. The device of claim 10, further comprising a fastener for locking the bezel to the housing so that tightening the fastener moves the bezel toward the housing to compress the touch screen therebetween.

12. A method of assembling an electronic device, comprising:
removably mounting a touch screen on a housing so that a first surface of the touch screen faces out from the housing to display output and receive contact input from a user; and
establishing electrical contact between a plurality of first electrical contacts located on a second surface of the touch screen and a plurality of second electrical contacts mounted on the housing and coupled to circuitry within the housing, the first electrical contacts conductively coupled to the touch screen to receive therefrom signals corresponding to contact input to the touch screen.

13. The method of claim 12, further comprising coupling a bezel to the housing locking at least a portion of a perimeter of the touch screen against the housing.

14. The method of claim 12, wherein the touch screen is mounted on the housing by insertion through a slot, further comprising removably mounting a lid member over the slot to lock the touch screen in a desired position within the housing.

15. The method of claim 14, wherein the lid member is semi-permanently coupled over the slot so that the lid member is removable from the housing without damaging the housing.

16. The method of claim 12, wherein the second electrical contacts include one of pogo pins and leaf springs.

17. The method of claim 12, wherein the first electrical contacts are bonded to the second surface of the touch screen.

18. The method of claim 12, further comprising releasably securing the first electrical contacts to the second electrical contacts using adhesive.

19. The method of claim 13, wherein the bezel is coupled to the housing by a fastener, further comprising tightening the fastener to move the bezel toward the housing compressing the touch screen between the housing and the bezel.
